(19) United States
(12) Patent Application Publication
(10) Pub. No.: US 2025/0228045 A1
(43) Pub. Date: Jul. 10, 2025

(54) LIGHT-EMITTING ELEMENT AND ELECTRONIC DEVICE INCLUDING THE SAME

(71) Applicant: Samsung Display Co., LTD., Yongin-si (KR)

(72) Inventors: JOONYONG PARK, Yongin-si (KR); SUKYOUNG YANG, Yongin-si (KR); DONGMIN LEE, Yongin-si (KR); HYUNEOK SHIN, Yongin-si (KR); MOONJUNG AN, Yongin-si (KR)

(21) Appl. No.: 19/012,707

(22) Filed: Jan. 7, 2025

(30) Foreign Application Priority Data
Jan. 8, 2024 (KR) 10-2024-0002989

(51) Int. Cl. H10H 20/841

(52) U.S. Cl. CPC H10H 20/841

(57) ABSTRACT

A light-emitting element includes: a first semiconductor layer, an active layer disposed on the first semiconductor layer, a second semiconductor layer disposed on the active layer, and a reflective layer including: a sub-reflective layer disposed on the second semiconductor layer and a barrier layer disposed on the sub-reflective layer and having a multilayer structure including niobium-titanium (Nb—Ti) alloy and chromium (Cr).

This application claims priority to Korean Patent Application No. 10-2024-0002989, filed on Jan. 8, 2024, and all the benefits accruing therefrom under 35 U.S.C. § 119, the content of which in its entirety is herein incorporated by reference.

### BACKGROUND

### 1. Field

Embodiments provide generally to a light-emitting element. More particularly, embodiments relate to a light-emitting element and an electronic device including the same.

### 2. Description of the Related Art

A light-emitting diode (“LED”) is an element that converts electrical signals into light forms such as infrared and visible light by the characteristics of compound semiconductor. In particular, the light-emitting diode is a semiconductor element that injects holes and electrons when a forward voltage is applied to a P-N diode, and converts the energy generated by recombination of holes and electrons into light energy.

### SUMMARY

Embodiments provide a light-emitting element with improved luminous efficiency.

Embodiments provide an electronic device including the light-emitting element.

A light-emitting element in an embodiment of the disclosure includes a first semiconductor layer, an active layer disposed on the first semiconductor layer, a second semiconductor layer disposed on the active layer, and a reflective layer including: a sub-reflective layer disposed on the second semiconductor layer and a barrier layer disposed on the sub-reflective layer and having a multilayer structure including niobium-titanium (Nb—Ti) alloy and chromium (Cr).

In an embodiment, the barrier layer may include a first layer including Nb—Ti alloy, a second layer disposed on the first layer and including Cr, and a third layer disposed on the second layer and including Nb—Ti alloy.

In an embodiment, each of the first and third layers may include about 50 atomic percent (at %) to about 60 at % of niobium (Nb) and about 40 at % to about 50 at % of titanium (Ti).

In an embodiment, a thickness of each of the first and third layers may range from about 100 nanometers (nm) to about 200 nm.

In an embodiment, the sub-reflective layer may include aluminum (Al).

In an embodiment, a thickness of the sub-reflective layer may range from about 200 nm to about 300 nm.

In an embodiment, the barrier layer may include a first layer including Nb—Ti alloy, a second layer disposed on the first layer and including chromium (Cr), and a third layer disposed on the second layer and including nickel (Ni).

In an embodiment, the first layer may include about 50 at % to about 60 at % of Nb and about 40 at % to about 50 at % of Ti.

In an embodiment, the reflective layer may further include an anti-corrosion layer disposed on the sub-reflective layer and including metal and a metal oxide layer disposed on the anti-corrosion layer.

In an embodiment, the light-emitting element may further include a connection layer disposed on the barrier layer and including an alloy.

In an embodiment, the anti-corrosion layer may include Cr, the metal oxide layer may include ITO, and the connection layer may include tin-silver-copper (Sn—Ag—Cu) alloy.

An electronic device in an embodiment of the disclosure includes a display device and a processor which controls the display device, the display device includes a pixel electrode disposed on a substrate, a light-emitting element disposed on the pixel electrode, extending perpendicular to the pixel electrode in a cross section, and including: a first semiconductor layer, an active layer disposed on the first semiconductor layer, a second semiconductor layer disposed on the active layer, and a reflective layer including: a sub-reflective layer disposed on the second semiconductor layer and a barrier layer disposed on the sub-reflective layer and having a multilayer structure including Nb—Ti alloy and Cr, and a common electrode disposed on the light-emitting element.

In an embodiment, the barrier layer may include a first layer including Nb—Ti alloy, a second layer disposed on the first layer and including Cr, and a third layer disposed on the second layer and including Nb—Ti alloy.

In an embodiment, each of the first and third layers may include about 50 at % to about 60 at % of Nb and about 40 at % to about 50 at % of Ti.

In an embodiment, a thickness of each of the first and third layers may range from about 100 nm to about 200 nm.

In an embodiment, the sub-reflective layer may include Al.

In an embodiment, a thickness of the sub-reflective layer may range from about 200 nm to about 300 nm.

In an embodiment, the barrier layer may include a first layer including Nb—Ti alloy, a second layer disposed on the first layer and including Cr, and a third layer disposed on the second layer and including Ni.

In an embodiment, the first layer may include about 50 at % to about 60 at % of Nb and about 40 at % to about 50 at % of Ti.

In an embodiment, the reflective layer may further include an anti-corrosion layer disposed on the sub-reflective layer and including metal and a metal oxide layer disposed on the anti-corrosion layer.

A light-emitting element in an embodiment of the disclosure may include a plurality of semiconductor layers, an active layer disposed between the plurality of semiconductor layers, and a reflective layer disposed on the active layer. Here, the reflective layer may include a sub-reflective layer including Al and a barrier layer having a multilayer structure including Nb—Ti alloy and Cr. Accordingly, when the light-emitting element is transferred on a substrate by thermocompression at a relatively high temperature, the occurrence of void defects due to Al diffusion in the sub-reflective layer may be suppressed, and the increase in resistance of the sub-reflective layer may be minimized. In this case, the luminous efficiency of the light-emitting element may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating an embodiment of a display device according to the disclosure.

FIG. 2 is a cross-sectional view taken along line I-I′ of FIG. 1.

FIG. 3 is an enlarged cross-sectional view of area A of FIG. 2.

FIG. 4 is an enlarged cross-sectional view of area B of FIG. 3.

FIG. 5 is an enlarged plan view of a part of a display area of FIG. 1.

FIG. 6 is a graph illustrating a surface resistance of a sub-reflective layer according to comparative example and embodiment.

FIG. 7 is a block diagram illustrating an electronic device according to an embodiment of the present disclosure.

### DETAILED DESCRIPTION

Hereinafter, a display device in embodiments of the disclosure will be explained in detail with reference to the accompanying drawings. The same reference numerals are used for the same components in the drawings, and redundant descriptions of the same components will be omitted.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

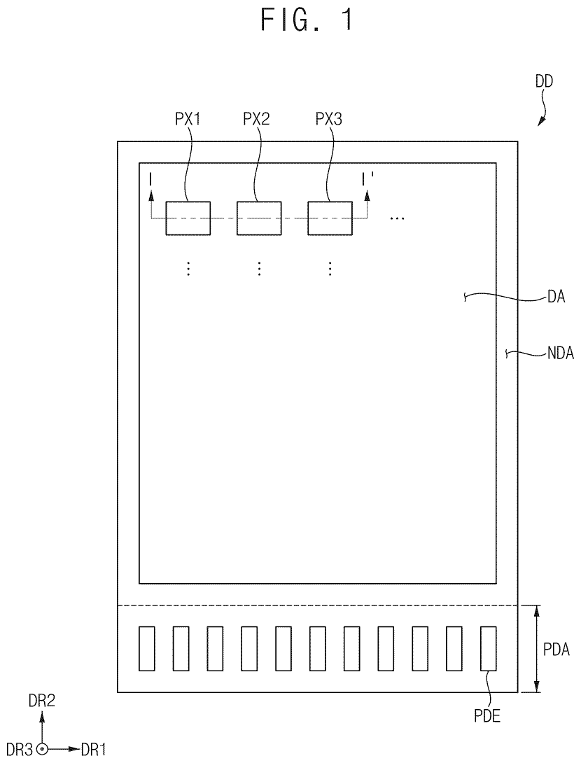

FIG. 1 is a plan view illustrating an embodiment of a display device according to the disclosure.

Referring to FIG. 1, the display device DD in an embodiment of the disclosure may include a display area DA and a non-display area NDA. The display area DA may be an area that may display an image by generating light or adjusting the transmittance of light provided from an external light source. The non-display area NDA may be an area that does not display images. The non-display area NDA may be disposed around the display area DA. In an embodiment, the non-display area NDA may surround an entirety of the display area DA, for example.

The display area DA may include a plurality of pixel areas. The pixel areas may be disposed in a matrix form along a first direction DR1 and a second direction DR2 crossing the first direction DR1. In an embodiment, the pixel areas may include a first pixel area PX1, a second pixel area PX2, and a third pixel area PX3, for example.

Each of the first pixel area PX1, the second pixel area PX2, and the third pixel area PX3 may mean an area where light emitted from a light-emitting element is emitted to the outside of the display device DD. In an embodiment, the first pixel area PX1 may emit first light, the second pixel area PX2 may emit second light, and the third pixel area PX3 may emit third light, for example. In an embodiment, the first light may be red light, the second light may be green light, and the third light may be blue light. However, the invention is not limited thereto. In an embodiment, the first, second, and third pixel areas PX1, PX2, and PX3 may be combined to emit yellow, cyan, and magenta lights, for example.

The first, second, and third pixel areas PX1, PX2, and PX3 may emit light of four or more colors. In an embodiment, the first, second, and third pixel areas PX1, PX2, and PX3 may be combined to emit at least one of yellow, cyan, and magenta lights in addition to red, green, and blue lights, for example. In addition, the first, second, and third pixel areas PX1, PX2, and PX3 may be combined to emit more white light.

Each of the first pixel area PX1, the second pixel area PX2, and the third pixel area PX3 may have a triangular planar shape, a square planar shape, a circular planar shape, an oval planar shape, or the like. In an embodiment, each of the first pixel area PX1, the second pixel area PX2, and the third pixel area PX3 may have a quadrangular shape, e.g., a rectangular planar shape. However, the embodiments of the disclosure are not limited, and each of the first pixel area PX1, the second pixel area PX2, and the third pixel area PX3 may have a different planar shape.

The non-display area NDA may include a pad area PDA. The pad area PDA may be disposed away from one side of the display area DA. In an embodiment, the pad area PDA may have a shape extending in the first direction DR1, for example.

A plurality of lines may be disposed in the non-display area NDA, and a plurality of pad electrodes PDE may be disposed in the pad area PDA. The lines may electrically connect pad electrodes PDE and the pixel areas. In an embodiment, the lines may include data signal lines, scan signal lines, light-emitting control signal lines, power voltage lines, or the like, for example.

The pad electrodes PDE may be spaced apart from each other in the first direction DR1. In an embodiment, each of the pad electrodes PDE may include metal, alloy, metal nitride, conductive metal oxide, transparent conductive material, or the like, for example. These may be used alone or in any combinations with each other.

In this specification, a plane may be defined as the first direction DR1 and the second direction DR2 crossing the first direction DR1. In an embodiment, the first direction DR1 may be perpendicular to the second direction DR2, for example. In addition, the third direction DR3 may be perpendicular to the plane.

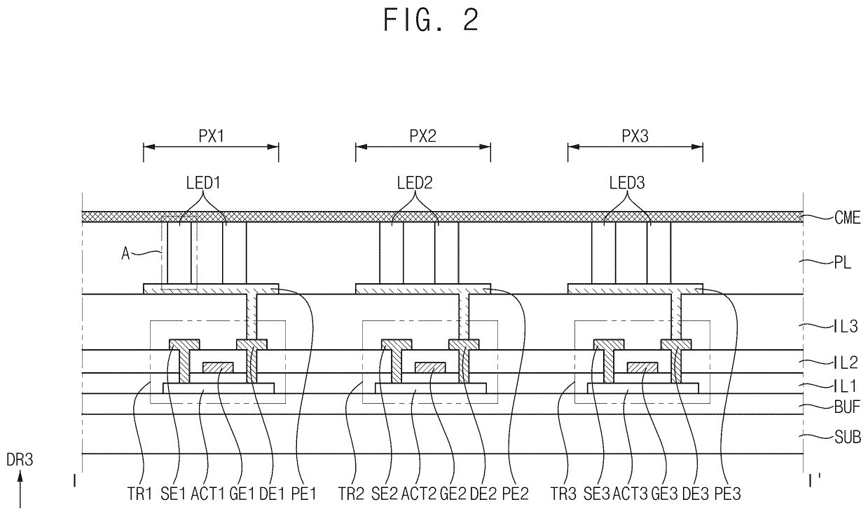

FIG. 2 is a cross-sectional view taken along line I-I′ of FIG. 1.

Referring to FIG. 2, the display device DD in an embodiment of the disclosure may include a substrate SUB, a buffer layer BUF, first, second, and third transistors TR1, TR2, and TR3, first, second, and third insulating layers IL1, IL2, and IL3, first, second, and third pixel electrodes PE1, PE2, and PE3, first, second, and third light-emitting elements LED1, LED2, and LED3, a planarization layer PL, and a common an electrode CME.

Here, the first transistor TR1 may include a first active pattern ACT1, a first gate electrode GE1, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

The substrate SUB may include a transparent material or an opaque material. The substrate SUB may include or consist of a transparent resin substrate. In embodiments, the transparent resin substrate may include a polyimide substrate. In this case, the polyimide substrate may include a first organic layer, a first barrier layer, a second organic layer, or the like. In an alternative embodiment, the substrate SUB may include a quartz substrate, synthetic quartz substrate, calcium fluoride substrate, F-doped quartz substrate, a soda-lime glass substrate, a non-alkali glass substrate, or the like. These may be used alone or in any combinations with each other.

The buffer layer BUF may be disposed on the substrate SUB. The buffer layer BUF may prevent metal atoms or impurities from diffusing from the substrate SUB to the first, second, and third transistors TR1, TR2, and TR3. In addition, the buffer layer BUF may improve the flatness of the surface of the substrate SUB when the surface of the substrate SUB is not uniform. In an embodiment, the buffer layer BUF may include an inorganic material such as silicon oxide, silicon nitride, silicon oxynitride, or the like, for example. These may be used alone or in combination.

The first, second, and third active patterns ACT1, ACT2, and ACT3 may be disposed on the buffer layer BUF. Each of the first, second, and third active patterns ACT1, ACT2, and ACT3 may include a metal oxide semiconductor, an inorganic semiconductor (e.g., amorphous silicon, poly silicon), or an organic semiconductor. Each of the first, second, and third active patterns ACT1, ACT2, and ACT3 may include a source region, a drain region, and a channel region disposed between the source region and the drain region. The first, second, and third active patterns ACT1, ACT2, and ACT3 may be formed through the same process and may include the same material as each other.

The metal oxide semiconductor may include a binary compound (ABₓ), a ternary compound (ABₓC_{y}), a quaternary compound (ABₓC_{y}D_{z}), or the like including or consisting of indium (In), zinc (Zn), gallium (Ga), tin (Sn), titanium (Ti), aluminum (Al), hafnium (Hf), zirconium (Zr), magnesium (Mg), or the like. In an embodiment, the metal oxide semiconductor may include zinc oxide (ZnOₓ), gallium oxide (GaOₓ), tin oxide (SnOₓ), indium oxide (InOₓ), indium gallium oxide (“IGO”), indium zinc oxide (“IZO”), indium tin oxide (“ITO”), indium zinc tin oxide (“IZTO”), indium gallium zinc oxide (“IGZO”), or the like, for example. These may be used alone or in any combinations with each other.

The first insulating layer IL1 may be disposed on the buffer layer BUF. The first insulating layer IL1 may sufficiently cover the first, second, and third active patterns ACT1, ACT2, and ACT3, and may have a substantially flat upper surface without creating steps around the first, second, and third active patterns ACT1, ACT2, and ACT3. In an alternative embodiment, the first insulating layer IL1 may cover the first, second, and third active patterns ACT1, ACT2, and ACT3, and may be disposed with a thickness measured in a thickness direction (e.g., the third direction DR3) perpendicular to a main plane extension direction (e.g., the first and second directions DR1 and DR2 defining a main plane) of the substrate SUB, and the thickness may be constant along the profile of each of the first, second, and third active patterns ACT1, ACT2, and ACT3 in the main plane extension direction. In an embodiment, the first insulating layer IL1 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like, for example. These may be used alone or in any combinations with each other.

The first, second, and third gate electrodes GE1, GE2, and GE3 may be disposed on the first insulating layer IL1. The first gate electrode GE1 may overlap the channel area of the first active pattern ACT1, the second gate electrode GE2 may overlap the channel area of the second active pattern ACT2, and the third gate electrode GE3 may overlap the channel area of the third active pattern ACT3.

Each of the first, second, and third gate electrodes GE1, GE2, and GE3 may include metal, alloy metal nitride, conductive metal oxide, transparent conductive material, or the like. In embodiments, the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. In embodiments, the conductive metal oxide may include ITO, IZO, or the like. In addition, embodiments of the metal nitride include aluminum nitride (AlNₓ), tungsten nitride (WNₓ), chromium nitride (CrNₓ), or the like. These may be used alone or in any combinations with each other.

The first, second, and third gate electrodes GE1, GE2, and GE3 may be formed through the same process and may include the same material as each other.

The second insulating layer IL2 may be disposed on the first insulating layer IL1. The second insulating layer IL2 may sufficiently cover the first to third gate electrodes GE1, GE2, and GE3, and may have a substantially flat upper surface without creating steps around the first, second, and third gate electrodes GE1, GE2, and GE3. In an alternative embodiment, the second insulating layer IL2 may cover the first, second, and third gate electrodes GE1, GE2, and GE3, and may be disposed with a uniform thickness along the profile of each of the first, second, and third gate electrodes GE1, GE2, and GE3. In an embodiment, the second insulating layer IL2 may include an inorganic material such as silicon oxide, silicon nitride, silicon carbide, silicon oxynitride, silicon oxycarbide, or the like, for example. These may be used alone or in any combinations with each other.

The first, second, and third source electrodes SE1, SE2, and SE3 may be disposed on the second insulating layer IL2. The first source electrode SE1 may be connected to the source region of the first active pattern ACT1 through a contact hole penetrating the first and second insulating layers IL1 and IL2. The second source electrode SE2 may be connected to the source region of the second active pattern ACT2 through a contact hole penetrating the first and second insulating layers IL1 and IL2. The third source electrode SE3 may be connected to the source region of the third active pattern ACT3 through a contact hole penetrating the first and second insulating layers IL1 and IL2.

The first, second, and third drain electrodes DE1, DE2, and DE3 may be disposed on the second insulating layer IL2. The first drain electrode DE1 may be connected to the drain region of the first active pattern ACT1 through a contact hole penetrating the first and second insulating layers IL1 and IL2. The second drain electrode DE2 may be connected to the drain region of the second active pattern ACT2 through a contact hole penetrating the first and second insulating layers IL1 and IL2. The third drain electrode DE3 may be connected to the drain region of the third active pattern ACT3 through a contact hole penetrating the first and second insulating layers IL1 and IL2.

In an embodiment, each of the first, second, and third source electrodes SE1, SE2, and SE3 may include metal, alloy, metal nitride, conductive metal oxide, transparent conductive material, or the like, for example. These may be used alone or in any combinations with each other. The first, second, and third drain electrodes DE1, DE2, and DE3 are formed through the same process as the first, second, and third source electrodes SE1, SE2, and SE3, and may include the same material as that of the first, second, and third source electrodes SE1, SE2, and SE3.

The third insulating layer IL3 may be disposed on the second insulating layer IL2. The third insulating layer IL3 may sufficiently cover the first, second, and third source electrodes SE1, SE2, and SE3 and the first, second, and third drain electrodes DE1, DE2, and DE3. The third insulating layer IL3 may include an organic material. In an embodiment, the third insulating layer IL3 may include phenolic resin, polyacrylates resin, polyimides rein, polyamides resin, siloxane resin, epoxy resin, or the like, for example. These may be used alone or in any combinations with each other.

The first, second, and third pixel electrodes PE1, PE2, and PE3 may be disposed on the third insulating layer IL3. In an embodiment, the third insulating layer IL3 may be a via-insulating layer, but the disclosure is not limited thereto. The first pixel electrode PE1 may overlap the first pixel area PX1, the second pixel electrode PE2 may overlap the second pixel area PX2, and the third pixel electrode PE3 may overlap the third pixel area PX3. The first pixel electrode PE1 may be connected to the first drain electrode DE1 (or the first source electrode SE1) through a contact hole penetrating the third insulating layer IL3, the second pixel electrode PE2 may be connected to the second drain electrode DE2 (or the second source electrode SE2) through a contact hole penetrating the third insulating layer IL3. In addition, the third pixel electrode PE3 may be connected to the third drain electrode DE3 (or third source electrode SE3) through a contact hole penetrating the third insulating layer IL3.

In an embodiment, each of the first, second, and third pixel electrodes PE1, PE2, and PE3 may include metal, alloy, metal nitride, conductive metal oxide, transparent conductive material, or the like, for example. These may be used alone or in any combinations with each other.

Since the first, second, and third pixel electrodes PE1, PE2, and PE3 serve to bond to the first, second, and third light-emitting elements LED1, LED2, and LED3, which will be described later, respectively, in order to reduce the contact resistance between each of the first, second, and third pixel electrodes PE1, PE2, and PE3 and the first light-emitting element LED1, the second light-emitting element LED2, or the third light-emitting element LED3, it is desirable to lower the sheet resistance of the first, second, and third pixel electrodes PE1, PE2, and PE3. In an embodiment, each of the first, second, and third pixel electrodes PE1, PE2, and PE3 may have a two-layer structure including titanium (Ti)/copper (Cu). However, the disclosure is not limited thereto.

The first, second, and third pixel electrodes PE1, PE2, and PE3 may be formed through the same process and may include the same material as each other. In an embodiment, each of the first, second, and third pixel electrodes PE1, PE2, and PE3 may operate as an anode or a cathode, for example.

The first light-emitting element LED1 may be disposed on the first pixel electrode PE1, the second light-emitting element LED2 may be disposed on the second pixel electrode PE2, and the third light-emitting element LED3 may be disposed on the third pixel electrode PE3. The first light-emitting element LED1 may overlap the first pixel area PX1, the second light-emitting element LED2 may overlap the second pixel area PX2, and the third light-emitting element LED3 may overlap the third pixel area PX3. In an embodiment, the first light-emitting element LED1 may be vertically disposed on the first pixel electrode PE1, the second light-emitting element LED2 may be vertically disposed on the second pixel electrode PE2, and the third light-emitting element LED3 may be vertically disposed on the third pixel electrode PE3. However, the disclosure is not limited thereto.

In an embodiment, the first, second, and third light-emitting elements LED1, LED2, and LED3 may be individually or in plural pieces picked up on a wafer by a transfer mechanism and transferred on the substrate SUB, thereby being bonded the first, second, and third pixel electrodes PE1, PE2, and PE3, respectively, for example. In this case, the first, second, and third light-emitting elements LED1, LED2, and LED3 may be transferred on the substrate SUB using a thermocompression method at a relatively high temperature (e.g., about 250 degrees Celsius (° C.) to about 310° C.).

The first light-emitting element LED1 may generate first light, the second light-emitting element e LED2 may generate second light, and the third light-emitting element LED3 may generate third light. In an embodiment, the first light may be red light, the second light may be green light, and the third light may be blue light, for example. However, the disclosure is not limited thereto.

In an embodiment, each of the first, second, and third light-emitting elements LED1, LED2, and LED3 may be a micro light-emitting diode. The stacked structure of each of the first, second, and third light-emitting elements LED1, LED2, and LED3 will be described later.

The planarization layer PL may be disposed on the third insulating layer IL3. The planarization layer PL may be disposed to surround the first light-emitting element LED1, the second light-emitting element LED2, and the third light-emitting element LED3. The planarization layer PL may be a layer for flattening steps caused by the first light-emitting element LED1, the second light-emitting element LED2, and the third light-emitting element LED3. In an embodiment, an upper surface of the planarization layer PL may be disposed at the same level as an upper surface of each of the first, second, and third light t emitting elements LED1, LED2, and LED3, for example. However, the disclosure is not limited thereto.

The planarization layer PL may include an organic material. In an embodiment, the planarization layer PL may include an organic material such as phenol resin, acrylic resin, polyimide resin, polyamide resin, siloxane resin, epoxy resin, or the like, for example. These may be used alone or in any combinations with each other.

The common electrode CME may be disposed on the planarization layer PL. The common electrode CME may be disposed on an entirety of the surface of the display area DA. That is, the common electrode CME may be an electrode commonly disposed in the first pixel area PX1, the second pixel area PX2, and the third pixel area PX3. In an embodiment, the common electrode CME may include metal, alloy, metal nitride, conductive metal oxide, transparent conductive material, or the like, for example. These may be used alone or in any combinations with each other. The common electrode CME may act as a cathode or anode.

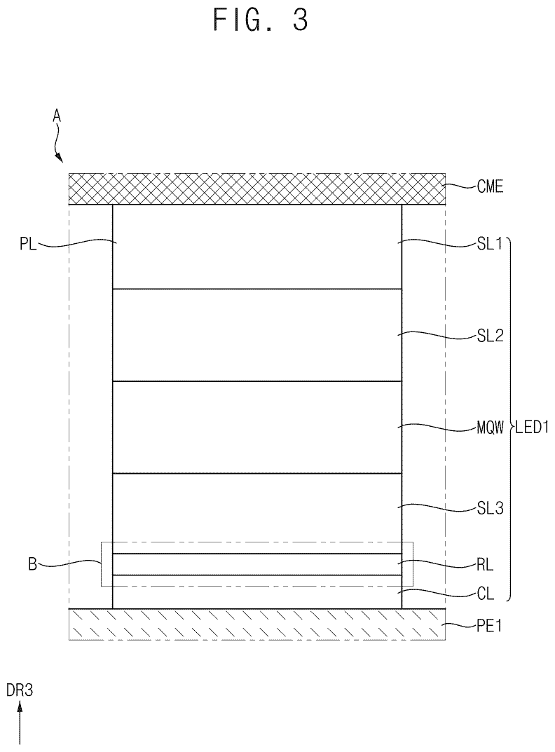

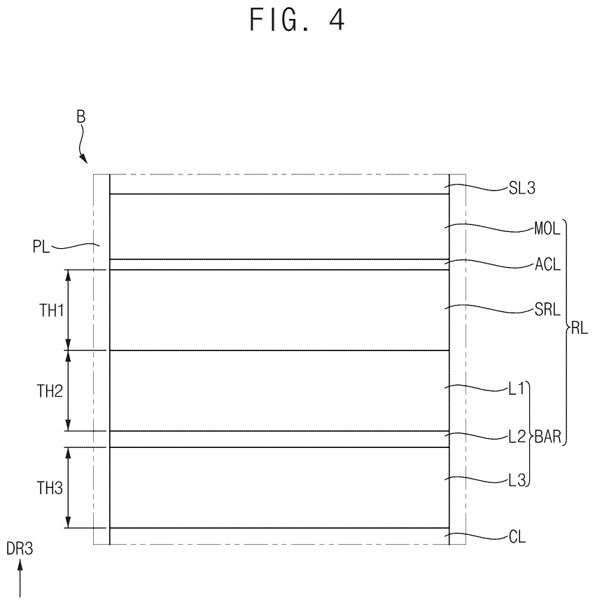

FIG. 3 is an enlarged cross-sectional view of area A of FIG. 2. FIG. 4 is an enlarged cross-sectional view of area B of FIG. 3. Specifically, FIG. 3 is an enlarged cross-sectional view of the first light-emitting element LED1 of FIG. 2, and FIG. 4 is an enlarged cross-sectional view of a reflective layer RL of FIG. 3. The stacked structure of each of the second and third light-emitting elements LED2 and LED3 may be substantially the same as the stacked structure of the first light-emitting element LED1. Therefore, the following description will focus on the stacked structure of the first light-emitting element LED1.

Referring to FIG. 3, the first light-emitting element LED1 may include a first semiconductor layer SL1, a second semiconductor layer SL2, an active layer MQW, a third semiconductor layer SL3, the reflective layer RL, and a connection layer CL sequentially disposed between the first pixel electrode PE1 and the common electrode CME along a direction opposite to the third direction DR3.

The first semiconductor layer SL1 may contact the common electrode CME. In an embodiment, the first semiconductor layer SL1 may include an undoped semiconductor, for example. The first semiconductor layer SL1 may include the same material as that of the second semiconductor layer SL2, but may include a material that is not doped with an n-type or p-type dopant. In an embodiment, the first semiconductor layer SL1 may include undoped InAlGaN, GaN, AlGaN, InGaN, AlN, InN, or the like, for example. These may be used alone or in any combinations with each other. However, the disclosure is not limited thereto.

The second semiconductor layer SL2 may be disposed under the first semiconductor layer SL1. The second semiconductor layer SL2 may include an n-type semiconductor. In an embodiment, the second semiconductor layer SL2 may include AlGaInN, GaN, AlGaN, InGaN, AlN, InN, or the like doped with n-type, for example. These may be used alone or in any combinations with each other. The second semiconductor layer SL2 may be doped with an n-type dopant, and the n-type dopant may include Si, Ge, Sn, or the like. In an embodiment, the second semiconductor layer SL2 may include n-GaN doped with n-type Si, for example.

The active layer MQW may be disposed under the second semiconductor layer SL2. The active layer MQW may generate light (e.g., red light, green light, or blue light) by combining electron-hole pairs according to an electric signal applied through the second semiconductor layer SL2 and the third semiconductor layer SL3.

The active layer MQW may include a material with a single or multiple quantum well structure. In an embodiment, when the active layer MQW includes a material with a multiple quantum well structure, the active layer MQW may have a structure in which a plurality of well layers and a barrier layer are alternately stacked. In this case, the well layers may include InGaN, and the barrier layer may include GaN or AlGaN, for example. However, the disclosure is not limited thereto.

In an alternative embodiment, the active layer MQW may have a structure in which a semiconductor material with a relatively large band gap energy and a semiconductor material with a relatively small band gap energy are alternately stacked, and may include different group III to group V semiconductor materials depending on the wavelength of the emitted light. In an embodiment, when the semiconductor materials included in the active layer MQW include indium (In), the color of the emitted light may vary depending on a proportion of indium (In), for example. When the proportion of indium (In) decreases, the wavelength band of the emitted light may shift to the red wavelength band, and when the proportion of indium (In) increases, the wavelength band of the emitted light may shift to the blue wavelength band.

A superlattice layer may be disposed between the active layer MQW and the second semiconductor layer SL2. The superlattice layer may be a layer for relieving stress between the active layer MQW and the second semiconductor layer SL2. In an embodiment, the superlattice layer may include InGaN or GaN, for example. The superlattice layer may be omitted.

The third semiconductor layer SL3 may be disposed under the active layer MQW. The third semiconductor layer SL3 may include a p-type semiconductor. In an embodiment, the third semiconductor layer SL3 may include AlGaInN, GaN, AlGaN, InGaN, AlN, InN, or the like doped with p-type, for example. These may be used alone or in any combinations with each other. The third semiconductor layer SL3 may be doped with a p-type dopant, and the p-type dopant may include Mg, Zn, Ca, Se, Ba, or the like. In an embodiment, the third semiconductor layer SL3 may include p-GaN doped with p-type Mg, for example.

An electron blocking layer may be disposed between the active layer MQW and the third semiconductor layer SL3. The electron blocking layer may be a layer to suppress or prevent too many electrons from flowing into the active layer MQW. In an embodiment, the electron blocking layer may include p-AlGaN doped with p-type Mg, for example. The electron blocking layer may be omitted.

The reflective layer RL may be disposed under the third semiconductor layer SL3. The reflective layer RL may serve to reflect light emitted from the active layer MQW of the first light-emitting element LED1. The reflective layer RL may include a metal material that is conductive and has a relatively high light reflectance.

Referring further to FIG. 4, the reflective layer RL may include a metal oxide layer MOL, an anti-corrosion layer ACL, a sub-reflective layer SRL, and a barrier layer BAR sequentially disposed between the third semiconductor layer SL3 and the connection layer CL along the direction opposite to the third direction DR3.

The metal oxide layer MOL may be disposed under the third semiconductor layer SL3. In an embodiment, the metal oxide layer MOL may include ITO, for example. However, the disclosure is not limited thereto.

The anti-corrosion layer ACL may be disposed beneath the metal oxide layer MOL. The corrosion prevention layer ACL may prevent corrosion of the metal oxide layer MOL and the sub-reflective layer SRL. In an embodiment, the anti-corrosion layer ACL may include chromium (Cr), for example. However, the disclosure is not limited thereto.

The sub-reflective layer SRL may be disposed under the anti-corrosion layer ACL. The sub-reflective layer SRL may include a metal material that is conductive and has a relatively high light reflectance. In an embodiment, the sub-reflective layer SRL may include aluminum (Al), for example. However, the disclosure is not limited thereto.

A thickness TH1 of the sub-reflective layer SRL may range from about 200 nanometers (nm) to about 300 nm. When the thickness TH1 of the sub-reflective layer SRL is less than 200 nm, when the first light-emitting element LED1 is transferred on a substrate (e.g., the substrate SUB of FIG. 2) by thermocompression at a relatively high temperature (e.g., about 250° C. to about 310° C.), the increase in resistance of the sub-reflective layer SRL may be relatively large.

The barrier layer BAR may be disposed under the sub-reflective layer SRL. The barrier layer BAR may block or prevent the material of the sub-reflective layer SRL from spreading. In an embodiment, the barrier layer BAR may have a multilayer structure including niobium (Nb)-titanium (Ti) alloy and chromium (Cr). As the barrier layer BAR includes Nb—Ti alloy, when the first light-emitting element LED1 is transferred on a substrate (e.g., the substrate SUB of FIG. 2) by thermocompression at a relatively high temperature (e.g., about 250° C. to about 310° C.), the occurrence of void defects due to Al diffusion in the sub-reflective layer SRL may be suppressed.

In an embodiment, the barrier layer BAR may include a first layer L1 including Nb—Ti alloy, a second layer L2 disposed under the first layer L1, and including Cr, and a third layer L3 disposed under the second layer L2 and including Nb—Ti alloy.

In another embodiment, the barrier layer BAR may include the first layer L1 including Nb—Ti alloy, the second layer L2 disposed under the first layer L1 and including chromium (Cr), and the third layer L3 disposed under the second layer L2 and including Ni. In another embodiment, the barrier layer BAR may include the first layer L1 including Ni, the second layer L2 disposed under the first layer L1 and including Cr, and the third layer L3 disposed under the second layer L2 and including Nb—Ti alloy.

A thickness TH2 and TH3 of each of the first and third layers L1 and L3 may be different from the thickness TH1 of the sub-reflective layer SRL. In an embodiment, the thickness TH2 of the first layer L1 may range from about 100 nm to about 200 nm, and the thickness TH3 of the third layer L3 may range from about 100 nm to about 200 nm. When the thicknesses TH2 and TH3 of the first and third layers L1 and L3 are less than 100 nm, Al diffusion in the sub-reflective layer SRL may not be suppressed during the thermocompression process at a relatively high temperature.

In an embodiment, each of the first layer L1 and the third layer L3 may include about 50 atomic percent (at %) to about 60 at % of Nb and about 40 at % to about 50 at % of Ti. When Nb and Ti in each of the first layer L1 and the third layer L3 are outside the above range, Al diffusion in the sub-reflective layer SRL may not be suppressed during the thermocompression process at a relatively high temperature.

The connection layer CL may be disposed under the reflective layer RL. Specifically, the connection layer CL may be disposed under the barrier layer BAR. The first light-emitting element LED1 and the first pixel electrode PE1 may be bonded through the connection layer CL. The connection layer CL may serve to transmit a light-emitting signal from the first pixel electrode PE1 to the first light-emitting element LED1. The connection layer CL may be an ohmic connection electrode. In an alternative embodiment, the connection layer CL may be a Schottky connection electrode.

The connection layer CL may be disposed at the bottom of the first light-emitting element LED1 and may be disposed further away from the active layer MQW than the reflective layer RL. In an embodiment, the connection layer CL may include Au, Cu, Sn, Ag, Al, Ti, or the like, for example. These may be used alone or in any combinations with each other. In an embodiment, the connection layer CL may include tin-silver-copper (Sn—Ag—Cu) alloy. However, the disclosure is not limited thereto.

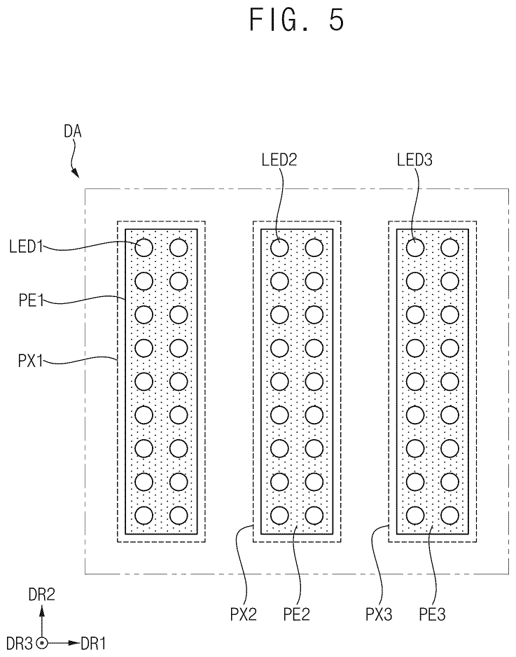

FIG. 5 is an enlarged plan view of a part of a display area of FIG. 1.

Referring to FIG. 5, the first light-emitting element LED1 may be disposed on the first pixel electrode PE1 disposed in the first pixel area PX1, the second light-emitting element LED2 may be disposed on the second pixel electrode PE2 disposed in the second pixel area PX2, and the third light-emitting element LED3 may be disposed on the third pixel electrode PE3 disposed in the third pixel area PX3.

In an embodiment, a plurality of first light-emitting elements LED1 may be arranged on one first pixel electrode PE1, and the first light-emitting elements LED1 may be arranged in a matrix form along the first direction DR1 and the second direction DR2 on one first pixel electrode PE1, for example.

In an embodiment, a plurality of second light-emitting elements LED2 may be arranged on one second pixel electrode PE2, and the second light-emitting elements LED2 may be arranged in a matrix form along the first direction DR1 and the second direction DR2 on one second pixel electrode PE2, for example.

In an embodiment, a plurality of third light-emitting elements LED3 may be arranged on one third pixel electrode PE3, and the third light-emitting elements LED3 may be arranged in a matrix form along the first direction DR1 and the second direction DR2 on one third pixel electrode PE3, for example.

Referring back to FIGS. 1, 2, 3, 4, and 5, a light-emitting element (e.g., the first light-emitting element LED1, the second light-emitting element LED2, or the third light-emitting element LED3) in an embodiment of the disclosure may include the plurality of semiconductor layers SL1, SL2, and SL3, the active layer MQW disposed between the plurality of semiconductor layers SL1, SL2, and SL3, and the reflective layer RL disposed under the active layer MQW. Here, the reflective layer RL may include the sub-reflective layer SRL including Al and the barrier layer BAR having a multilayer structure including Nb—Ti alloy and Cr. Accordingly, when the light-emitting element is transferred on the substrate SUB by thermocompression at a relatively high temperature, the occurrence of void defects due to Al diffusion in the sub-reflective layer SRL may be suppressed, and the increase in resistance of the sub-reflective layer SRL may be minimized. In this case, the luminous efficiency of the light-emitting element may be improved.

Hereinafter, the effects of the disclosure according to comparative examples and embodiment will be described.

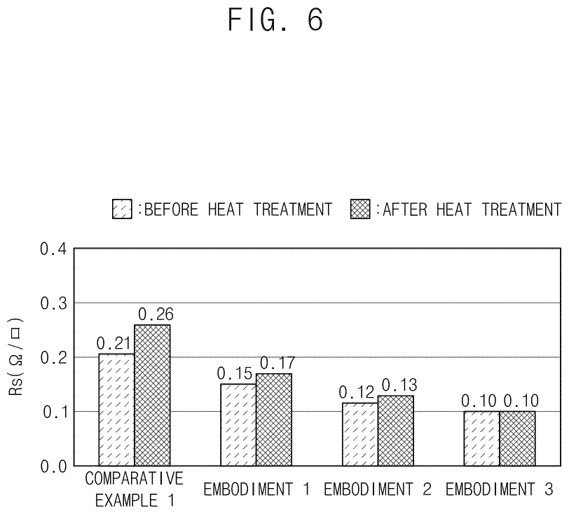

FIG. 6 is a graph illustrating a surface resistance of a sub-reflective layer according to comparative example and embodiment.

According to Comparative Example and Embodiments, a first metal layer was formed using Al on a glass substrate, and a second metal layer was formed on the first metal layer using Nb—Ti alloy. Here, the second metal layer includes about 60 at % of Nb and about 40 at % of Ti.

In Comparative Example 1, the first metal layer was formed to have a thickness of about 1500 angstroms (Å), and the second metal layer was formed to have a thickness of about 1000 Å.

In Embodiment 1, the first metal layer was formed to have a thickness of about 2000 Å, and the second metal layer was formed to have a thickness of about 1000 Å.

In Embodiment 2, the first metal layer was formed to have a thickness of about 2500 Å, and the second metal layer was formed to have a thickness of about 1000 Å.

In Embodiment 3, the first metal layer was formed to have a thickness of about 3000 Å, and the second metal layer was formed to have a thickness of about 1000 Å.

According to Comparative Example and Embodiments, heat treatment was performed on the first metal layer and the second metal layer formed on the glass substrate at about 450° C. for about 1 hour.

As a result, it may be confirmed that a diffusion layer was formed at an interface between the first metal layer and the second metal layer. The thickness of the diffusion layer according to Comparative Example and Embodiments is shown in Table 1 below.

TABLE 1

| | Comparative | Embodiment | Embodiment | Embodiment |
|---|---|---|---|---|
| | Example 1 | 1 | 2 | 3 |
| A thickness of | 480 | 470 | 470 | 450 |
| the diffusion | | | | |
| layer | | | | |

In addition, it may be confirmed that the increase in surface resistance Rs (in terms of ohm per square (Ω/□)) of the first metal layer after heat treatment according to Comparative Example 1 is greater than the increase in surface resistance Rs of the first metal layer after heat treatment according to Embodiments 1, 2, and 3.

Through this, the light-emitting element in embodiments of the disclosure includes the sub-reflection layer including Al and the barrier layer including Nb—Ti alloy, and the thickness of the sub-reflection layer ranges from about 200 nm to about 300 nm. In this case, it may be confirmed that the increase in resistance of the sub-reflective layer may be minimized after heat treatment at a relatively high temperature (i.e., 450° C.). In addition, it may be confirmed that after heat treatment at the relatively high temperature, voids are not formed due to Al diffusion in the sub-reflective layer.

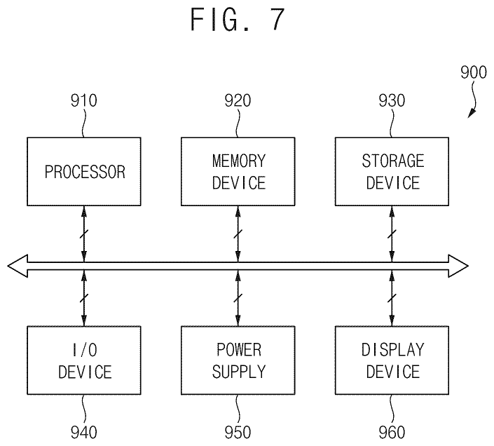

FIG. 7 is a block diagram illustrating an electronic device according to an embodiment of the present disclosure.

Referring to FIG. 7, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1 to 6. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The disclosure may be applied to various display devices. In an embodiment, the disclosure is applicable to various display devices such as display devices for vehicles, ships and aircraft, portable communication devices, display devices for exhibition or information transmission, medical display devices, or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims.

What is claimed is:

1. A light-emitting element comprising:
a first semiconductor layer;
an active layer disposed on the first semiconductor layer;
a second semiconductor layer disposed on the active layer; and
a reflective layer including:
a sub-reflective layer disposed on the second semiconductor layer; and
a barrier layer disposed on the sub-reflective layer and having a multilayer structure including niobium-titanium (Nb—Ti) alloy and chromium (Cr).

2. The light-emitting element of claim 1, wherein the barrier layer includes:
a first layer including niobium-titanium (Nb—Ti) alloy;
a second layer disposed on the first layer and including chromium (Cr); and
a third layer disposed on the second layer and including niobium-titanium (Nb—Ti) alloy.

3. The light-emitting element of claim 2, wherein each of the first and third layers includes about 50 at % to about 60 at % of niobium (Nb) and about 40 at % to about 50 at % of titanium (Ti).

4. The light-emitting element of claim 2, wherein a thickness of each of the first and third layers ranges from about 100 nanometers to about 200 nanometers.

5. The light-emitting element of claim 1, wherein the sub-reflective layer includes aluminum (Al).

6. The light-emitting element of claim 5, wherein a thickness of the sub-reflective layer ranges from about 200 nanometers to about 300 nanometers.

7. The light-emitting element of claim 1, wherein the barrier layer includes:
a first layer including niobium-titanium (Nb—Ti) alloy;
a second layer disposed on the first layer and including chromium (Cr); and
a third layer disposed on the second layer and including nickel (Ni).

8. The light-emitting element of claim 7, wherein the first layer includes about 50 at % to about 60 at % of niobium (Nb) and about 40 at % to about 50 at % of titanium (Ti).

9. The light-emitting element of claim 1, wherein the reflective layer further includes:
an anti-corrosion layer disposed on the sub-reflective layer and including metal; and
a metal oxide layer disposed on the anti-corrosion layer.

10. The light-emitting element of claim 9, further comprising:
a connection layer disposed on the barrier layer and including an alloy.

11. The light-emitting element of claim 10, wherein the anti-corrosion layer includes chromium (Cr), the metal oxide layer includes indium tin oxide, and the connection layer includes tin-silver-copper (Sn—Ag—Cu) alloy.

12. An electronic device comprising:
a display device; and
a processor which controls the display device,
wherein the display device includes:
a pixel electrode disposed on a substrate;
a light-emitting element disposed on the pixel electrode and extending perpendicular to the pixel electrode in a cross section, the light-emitting element including:
a first semiconductor layer;
an active layer disposed on the first semiconductor layer;
a second semiconductor layer disposed on the active layer; and
a reflective layer including:
a sub-reflective layer disposed on the second semiconductor layer; and
a barrier layer disposed on the sub-reflective layer and having a multilayer structure including niobium-titanium (Nb—Ti) alloy and chromium (Cr); and
a common electrode disposed on the light-emitting element.

13. The electronic device of claim 12, wherein the barrier layer includes:
a first layer including niobium-titanium (Nb—Ti) alloy;
a second layer disposed on the first layer and including chromium (Cr); and
a third layer disposed on the second layer and including niobium-titanium (Nb—Ti) alloy.

14. The electronic device of claim 13, wherein each of the first and third layers includes about 50 at % to about 60 at % of niobium (Nb) and about 40 at % to about 50 at % of titanium (Ti).

15. The electronic device of claim 13, wherein a thickness of each of the first and third layers ranges from about 100 nanometers to about 200 nanometers.

16. The electronic device of claim 12, wherein the sub-reflective layer includes aluminum (Al).

17. The electronic device of claim 16, wherein a thickness of the sub-reflective layer ranges from about 200 nanometers to about 300 nanometers.

18. The electronic device of claim 12, wherein the barrier layer includes:
a first layer including niobium-titanium (Nb—Ti) alloy;
a second layer disposed on the first layer and including chromium (Cr); and
a third layer disposed on the second layer and including nickel (Ni).

19. The electronic device of claim 18, wherein the first layer includes about 50 at % to about 60 at % of niobium (Nb) and about 40 at % to about 50 at % of titanium (Ti).

20. The electronic device of claim 12, wherein the reflective layer further includes:
an anti-corrosion layer disposed on the sub-reflective layer and including metal; and
a metal oxide layer disposed on the anti-corrosion layer.
